(19) United States
(12) Patent Application Publication
(10) Pub. No.: US 2023/0002905 A1
(43) Pub. Date: Jan. 5, 2023

(54) USE OF A CVD REACTOR FOR DEPOSITING TWO-DIMENSIONAL LAYERS

(71) Applicant: AIXTRON SE, Herzogenrath (DE)

(72) Inventors: Kenneth B. K. TEO, Cambridge (GB); Clifford MCALEESE, Cambridge (GB); Ben Richard CONRAN, Cambridge (GB)

(21) Appl. No.: 17/773,512

(22) PCT Filed: Oct. 30, 2020
(86) PCT No.: PCT/EP2020/080507

§ 371 Date: Apr. 29, 2022

(30) Foreign Application Priority Data
Nov. 5, 2019 (DE) 10 2019 129 788.5

(51) Int. Cl. C23C 16/52; C23C 16/46; C23C 16/458; C23C 16/455; C23C 16/26

(52) U.S. Cl. CPC C23C 16/52; C23C 16/46; C23C 16/4583; C23C 16/45565; C23C 16/45561; C23C 16/26; C23C 16/45557

(57) ABSTRACT

A two-dimensional layer is deposited onto a substrate in a CVD reactor, in which a process gas is fed into a process chamber. The process gas in the process chamber is brought to the substrate, and the substrate is heated to a process temperature. After a chemical reaction of the process gas, the layer forms on the surface. During or after the heating of the substrate to the process temperature, the process gas with a first mass flow rate is initially fed into the process chamber and then, while the substrate surface is being observed, the mass flow rate of the process gas is increased to a rate at which the layer growth begins, and subsequently the mass flow rate of the process gas is increased by a predetermined value, during which the layer is deposited. The beginning of the layer growth is identified by observing measurements from a pyrometer.

### RELATED APPLICATIONS

This application is a National Stage under 35 USC 371 of and claims priority to International Application No. PCT/EP2020/080507, filed 30 Oct. 2020, which claims the priority benefit of DE Application No. 10 2019 129 788.5, filed 5 Nov. 2019.

### FIELD OF THE INVENTION

The invention initially relates to a method for depositing a two-dimensional layer onto a substrate in a CVD reactor, in which a process gas is fed into a gas inlet element by means of a feed line, which has gas outlet openings that empty into a process chamber, in which the process gas or its decomposition products are brought into contact with a surface of a substrate in the process chamber, and in which the substrate is brought to a process temperature by means of a heating device, so that the two-dimensional layer is deposited onto the surface.

The invention further relates to the use of a CVD reactor for implementing the method.

### BACKGROUND

CVD reactors are known from DE 10 2011 056 589 A1 and DE 10 2010 016 471 A1, as well as from other comprehensive written prior art. DE 10 2004 007 984 A1 describes a method with which the temperature of a substrate surface can be measured with an optical measuring device. DE 10 2013 111 791 A1 describes the deposition of two-dimensional layers using a showerhead. WO 2017/029470 A1 describes the deposition of graphene with a reactor having a showerhead.

### SUMMARY OF THE INVENTION

The object of the invention is to technologically improve the method for depositing a two-dimensional layer and indicate a device that can be used for this purpose.

The object is achieved by the invention indicated in the claims, wherein the subclaims describe not just advantageous further developments of the invention indicated in the secondary claims, but also separate technical solutions of the object.

Initially and essentially, it is proposed that a gas flow of the process gas be fed into the process chamber with a first mass flow rate while heating or after heating the substrate to a process temperature. As a result of the gas flow with the first mass flow rate, a partial pressure of one or several reactive gases sets in that lies below a threshold value at which a solid layer is deposited onto the substrate. The start of feeding in the process gas can be made dependent on reaching a temperature. For example, it can be provided that feeding in the first gas flow starts when the heating process has ended, and the surface of the substrate has reached the process temperature. However, the first gas flow of the process gas can start being fed in even beforehand. The mass flow rate of the process gas is set so low that no growth of the two-dimensional layer is observed on the substrate surface. According to the invention, in particular after reaching the process temperature, the mass flow rate of the process gas is then incrementally or continuously, linearly or nonlinearly, increased until a growth of the layer on the substrate is observed. The partial pressure of the one or several reactive gases in the process chamber increases until the threshold value has been reached, at a second mass flow rate of the gas flow. This second mass flow rate of the process gas is subsequently increased to a third mass flow rate by a prescribed value, which can also be 0. The deposition of the two-dimensional layer then takes place at this third mass flow rate. The partial pressure of the one or several reactive gases is here set to a value lying above the threshold value. The value is selected in such a way that a layer is deposited onto the substrate during the flow of the process gas at the third mass flow rate, i.e., that layer growth takes place. Insular growth is observed while depositing two-dimensional layers according to methods in prior art, which are disclosed in particular in the publications mentioned at the outset. Because growth begins there at numerous germination sites on numerous different areas on the substrate, a layer fabricated in this way has a low layer quality. Apart from a two-dimensional layer, for example a graphene layer, an amorphous carbon layer or multiple layers can form. This disadvantage is to be eliminated with the method according to the invention or the use of a CVD reactor according to the invention. The objective is to indicate an optimal growth method for depositing a two-dimensional layer with a high quality. The approach according to the invention relates to controlling the gas flow in the growth phase, such that a partial pressure of the process gas is set above the substrate that lies above a threshold by a prescribed value, wherein the threshold value is defined by the partial pressure at which the state changes between nongrowth and growth. A CVD reactor used according to the invention has a gastight housing, which can be evacuated. The housing incorporates a gas inlet element, which can be fed by means of a feed line with the process gas consisting of one or several reactive gases, or alternatively with an inert gas. The gas inlet element can have a gas distribution chamber. For example, it can assume the form of a showerhead. The process gas can flow into a process chamber from a gas outlet plate that comprises a flat gas outlet surface. To this end, the gas outlet plate forms a plurality of uniformly distributed gas outlet openings. The gas outlet openings can be formed by the ends of tubes, which cross a cooling chamber directly adjacent to the gas outlet plate. The tubes are used to fluidly connect one or more gas distribution chambers with the gas outlet surface. A support surface of a susceptor, which can include a coated or uncoated graphite body, is spaced apart from the gas outlet surface. The susceptor accommodates the substrate on its support surface. Arranged on the side of the susceptor lying opposite the support surface is a heating device, for example a resistance heater, an infrared heater, or an inductive RF heater, with which the susceptor or the substrate can be heated to a process temperature. While heating the susceptor, during which an inert gas can be fed into the process chamber, but during which a smaller first gas flow of the process gas can also be fed into the process chamber, the surface temperature of the substrate is measured with an optical device. The optical device is optically connected with the surface of the substrate via a beam path so as to observe the surface of the substrate. To this end, the gas inlet element can have a window, made out of a material transparent to a wavelength of radiation emitted by the optical device, through which the beam path passes. The beam path can further pass through one of the tubes. In this regard, reference is made to the statements in DE 10 2004 007 984 A1, the disclosure content of which is also incorporated into the disclosure of this application in its entirety. The optical device can be a pyrometer, and is preferably a two-wavelength pyrometer, in which a spectrum is recorded in two different wavelength ranges, for example 350 to 1050 nm and 1050 to 1750 nm. A third spectrum can be calculated from the two spectra, and used to determine the surface temperature of the substrate. The spectra are used to determine a value, from which the surface temperature is ascertained. The latter can be depicted as a measuring curve. Surprisingly, the time progression of the value can be used not just to determine the temperature, but also to determine when layer growth starts or determine when multilayer growth starts. In addition, the measuring curve can be used to end the deposition process. It was observed that the measured value used to determine the temperature corresponds to a measuring curve that runs along a straight line over time before the layer deposition starts. The measuring curve of the value recorded by the optical measuring device over time essentially runs with a constant, in particular negative, gradient. The progression of the measuring curve was observed to change with the start of layer deposition. In particular, it was found that the gradient of the measuring curve rises slightly at the start of layer growth, and thereafter drops off again, so that a local maximum or minimum arises in the measuring curve. It was further observed that the value of the measuring curve gradient again becomes larger or smaller over time after running through the peak. A complete layer has been deposited at this point in time, or a multilayer growth or deposition of an amorphous carbon layer can be expected as of this point in time. The method according to the invention is used to increase the mass flow rate of the gas flow from the first mass flow rate until a first characteristic change becomes evident in the progression of the measuring curve, in particular until the gradient of the measuring curve measured with the optical measuring device increases for the first time. The mass flow rate of the process gas fed into the process chamber at this point in time is referred to as the second mass flow rate. The mass flow rate is then increased from the second mass flow rate by a prescribed value to a third mass flow rate, at which the layer is deposited. The prescribed value can be greater than 0. It can be at least 5 percent of the second mass flow rate, at least 10 percent of the second mass flow rate, or at least 20 percent of the second mass flow rate. However, it can also be about 20 percent of the second mass flow rate. It can also be at most 20 percent or at most 25 percent of the second mass flow rate. The progression of the measuring curve is further observed until another characteristic change in the measuring curve arises. This characteristic change in the progression of the measuring curve can be a renewed rise in the gradient of the measuring curve. If this event is found, the flow of the process gas is turned off. The layers deposited with the method according to the invention or the use according to the invention can be transition metal dichalcogenides. In particular, it can be the material pairs mentioned in DE 10 2013 111 791 A1, wherein the process gases mentioned there can be used to deposit these materials. For this reason, the disclosure content of DE 10 2013 111 791 A1 is also incorporated into this application in its entirety. It is especially preferable that graphene, MoS₂, MoSe₂, WS₂ or WSe₂ or hBN be deposited. In order to deposit graphene, a hydrocarbon is used as the process gas, for example methane. W(CO)₆ can be used for depositing tungsten compounds. A noble gas, for example argon, can be used as the carrier gas. However, it is also provided that borazine be used as the reactive gas while depositing hBN. In order to influence the growth rate, the process chamber height can be varied during deposition, i.e., the distance between the support surface of the susceptor and gas outlet surface. A sapphire substrate is preferably used as the substrate. However, silicon substrates or other substrates can also be used. According to the invention, it is possible to deposit two-dimensional layers, for example graphene, with only one reactive gas, for example borazine. However, it is also provided that the two-dimensional layers be deposited using two reactive gases, wherein one reactive gas contains the transition metal, and the other reactive gas contains a chalcogenide. In the case of sulfur, di-tert-butyl-sulfide is here preferably involved.

### BRIEF DESCRIPTION OF THE DRAWINGS

Exemplary embodiments of the invention will be described below based upon the attached drawings. Shown on:

FIG. 1 is a schematic cross section through a CVD reactor of a first exemplary embodiment, and a schematic view of the components of a gas mixing system required for explaining the invention,

FIG. 2 is a magnified view of the cutout II on FIG. 1,

FIG. 3 is a plot depicting the time progression of the process gases,

FIG. 4a is a plot depicting a measuring curve of a two-wave pyrometer during layer deposition,

FIG. 4b is an illustration according to FIG. 3 of the time progression of the gas flow of the reactive gas in the process chamber,

FIG. 5 is a plot depicting a measuring curve similar to FIG. 4a, but wherein the reactive gas has been fed into the process chamber over the entire time t,

FIG. 6 is an illustration according to FIG. 1 of a second exemplary embodiment,

FIG. 7 is a magnified view of the cutout VII on FIG. 6,

FIG. 8 is a plot illustrating the influence of a process chamber height h on layer growth at various total pressures.

### DETAILED DESCRIPTION

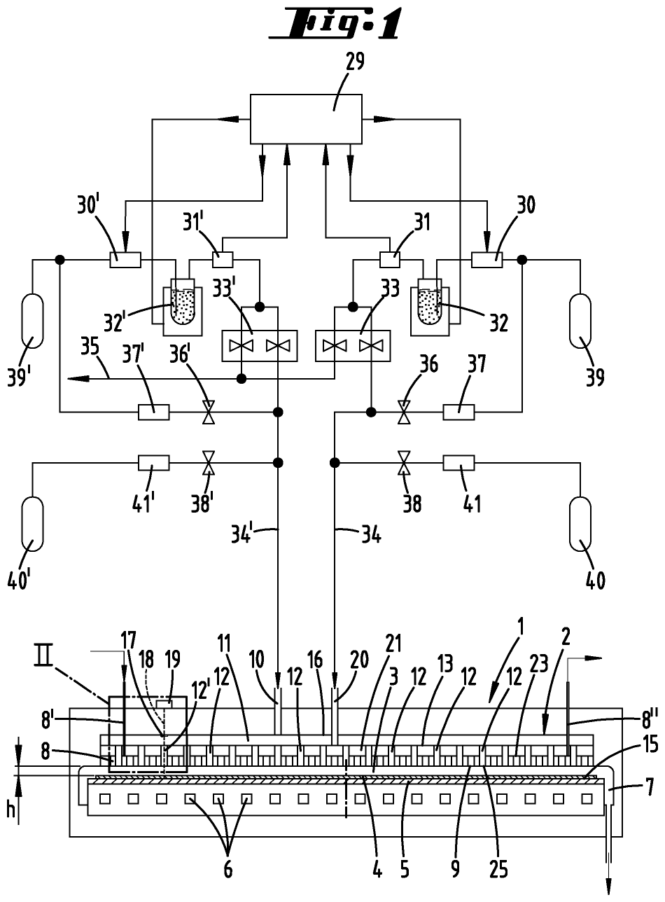

The device shown on FIGS. 1 and 6, 7 is a CVD reactor 1. The CVD reactor 1 has a housing, which is gastight and can be evacuated with a vacuum pump (not shown). The vacuum pump can be connected to a gas outlet element 7.

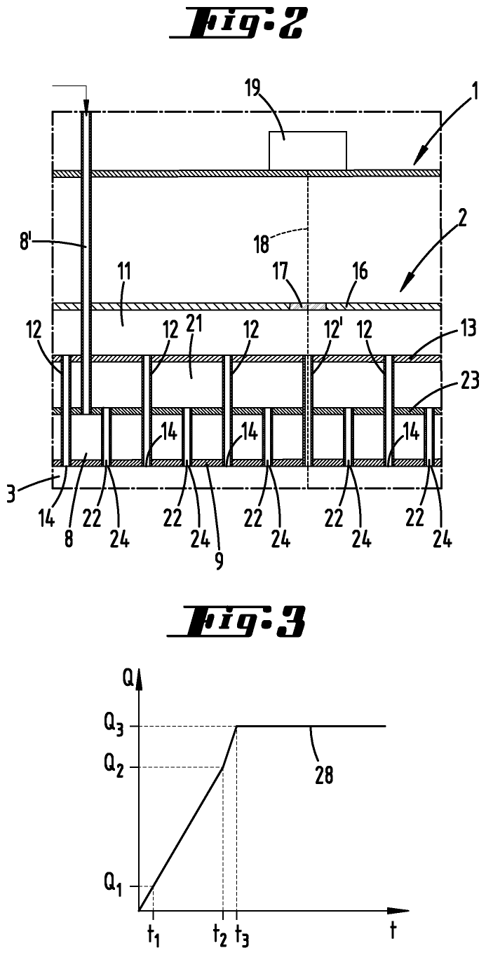

Located inside of the CVD reactor 1 is a gas inlet element 2, which has the shape of a shower head (showerhead). In the exemplary embodiment shown on FIGS. 1 and 2, the gas inlet element 2 has two gas distribution chambers 11, 21, into which a respective feed line 10, 20 empties, through which a gas can be fed into the respective gas distribution chamber 11, 21. The feed lines 10, 20 protrude through the wall of the housing. The gas distribution chambers 11, 21 are arranged vertically over each other. Located below the gas distribution chamber 21 is a cooling chamber 8. A coolant can be fed into the cooling chamber 8 through a feed line 8′. The coolant exits the cooling chamber 8 through a discharge line 8″. The feed line 8′ and discharge line 8″ protrude through a wall of the housing of the CVD reactor 1.

FIG. 1 further shows a cutout of a gas mixing system for providing the process gases. Two reactive gases are each generated by evaporating liquids or solids. The liquid or a powder is stored in gastight containers (bubblers 32, 32′). A mass flow controller 30, 30′ is used to feed a respective inert gas from an inert gas source 39, 39′ into the respective bubbler 32, 32′. The bubblers 32, 32′ are kept at a constant temperature in temperature baths. A vapor of the reactive gas transported with the inert gas acting as the carrier gas exits the respective bubbler 32, 32′. The concentration of reactive gas in the output flow is measured with a concentration measuring device 31, 31′. A device sold under the brand name “Epison” is here involved.

The two different gas lines for transporting the reactive gas can each be fed by means of a switching valve 33, 33′ into either a vent line 35 that conducts the gas by the reactor 1, or into a run line 34, 34′ that conducts the gas into the reactor 1.

Provided is a control device 29, which controls the temperature of the heating baths and mass flow controller 30, 30′. The measuring results of the concentration measuring device 31, 31′ are likewise fed to the control device 29.

The run line 34 of the branch of the gas supply shown on the right hand side of FIG. 1 empties into the feed line 20. The run line 34′ empties into the feed line 10.

Instead of the reactive gas, the mass flow controller 37, 37′ and valves 36, 36′ can also feed a carrier gas/inert gas into the gas inlet element 2. Reference numbers 40, 40′ denote sources for reactive gases, for example which are carbon compounds and in particular hydrocarbons, such as methanes, which are used for depositing graphene. These reactive gas sources 40, 40′ are connected in terms of flow with the run lines 34, 34′ via mass flow controllers 41, 41′ and valves 38, 38′.

As a consequence, the gas mixing system shown on FIG. 1 can optionally be used to feed two different reactive gases into the two separate gas distribution chambers 11, 21 simultaneously. However, it is also possible to sequentially feed methane into the gas distribution chamber 11 and an inert gas into the gas distribution chamber 21, and then feed borazine into the gas distribution chamber 21 and the inert gas into the gas distribution chamber 11, for example to deposit a sequence of layers comprised of graphene and hBN. In this way, heterogenous layer structures can be deposited via periodic switching.

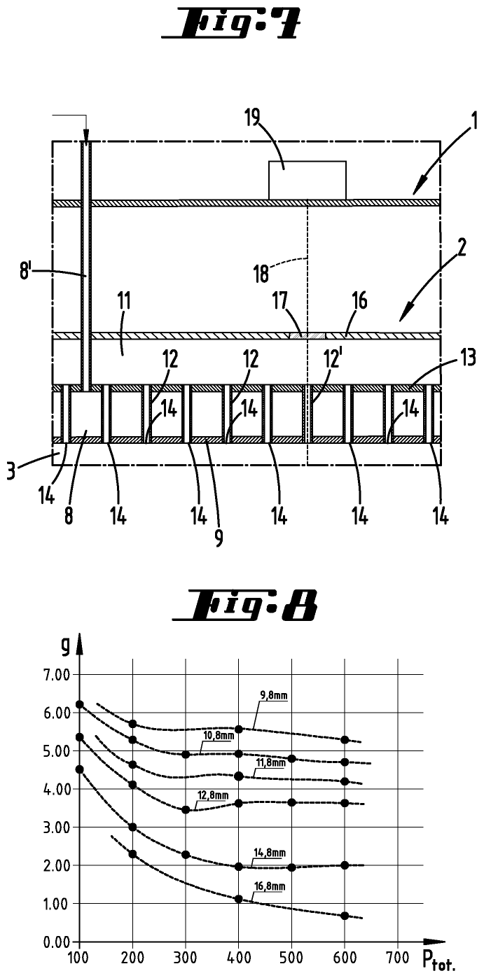

The exemplary embodiment of a CVD reactor 1 shown on FIGS. 6 and 7 essentially differs from the exemplary embodiment shown on FIGS. 1 and 2 in that only one gas distribution chamber 11 is provided. The latter is connected by tubes 12 with a gas outlet surface 25, so that process gas fed into the gas distribution chamber 11 can flow through the tubes 12 and into a process chamber 3.

The gas mixing system denoted on FIG. 6 has only one bubbler 32, into which a carrier gas is fed by means of the mass flow controller 30. The concentration of the vapor transported in the carrier gas can be determined with the concentration measuring device 31. The switching valve 33 can be used to feed the mass flow of the reactive gas into either a vent line 35 or into the run line 34. The inert gas can be fed into the run line 34 by means of the mass flow controller 37. To this end, the valve 36 must be opened.

The exemplary embodiment shown on FIGS. 1 and 2 additionally provides tubes 22 that connect a second gas distribution chamber 21 with the gas outlet surface 25. In the gas outlet surface 25 comprised of a gas outlet plate 9, gas outlet openings 14, 24 each connected with a tube 12, 22 are arranged distributed over the entire gas outlet surface 25. The tubes 22 are connected with an intermediate plate 23 that separates the gas distribution chamber 21 from the cooling chamber 8. The tubes 12 are connected with an intermediate plate 13, which separates the gas distribution chamber 11 from the gas distribution chamber 21.

A support surface 15 of a susceptor 5 comprised of coated or uncoated graphite extends at a distance h from the gas outlet surface 25. Undepicted lifting elements can be used to lift or lower the susceptor 5 and/or the gas inlet element 2. The lifting elements can be used to vary the distance h. FIG. 8 shows a plot illustrating the influence of varying the process chamber height on the growth rate of the deposited layer at different total pressures in the process chamber 3.

The susceptor 5 is heated from below by means of a heating device 6. The heating device can be a resistance heater, an IR heater, an RF heater, or some other power source with which thermal energy is fed to the susceptor 5.

The susceptor 5 is surrounded by a gas outlet element 7, through which gaseous reaction products and a carrier gas are discharged.

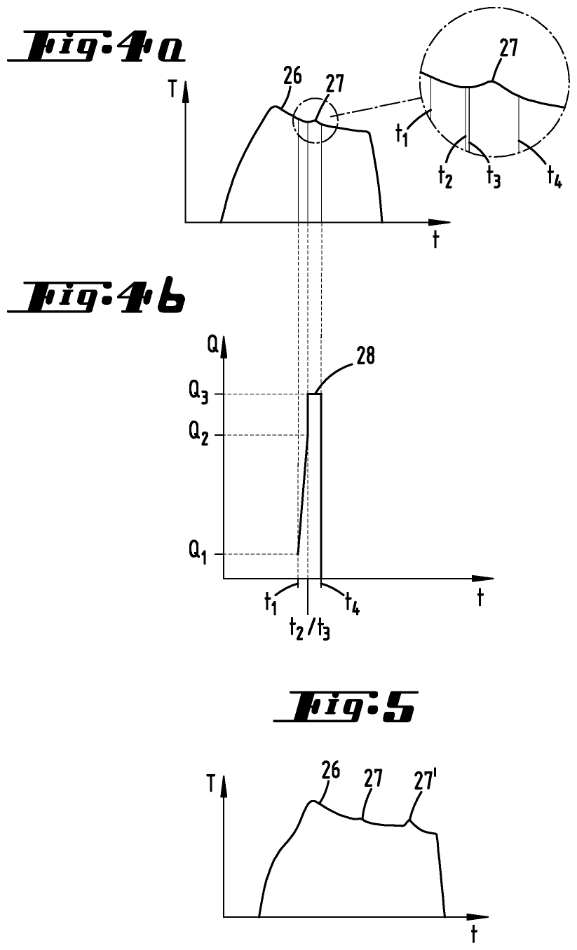

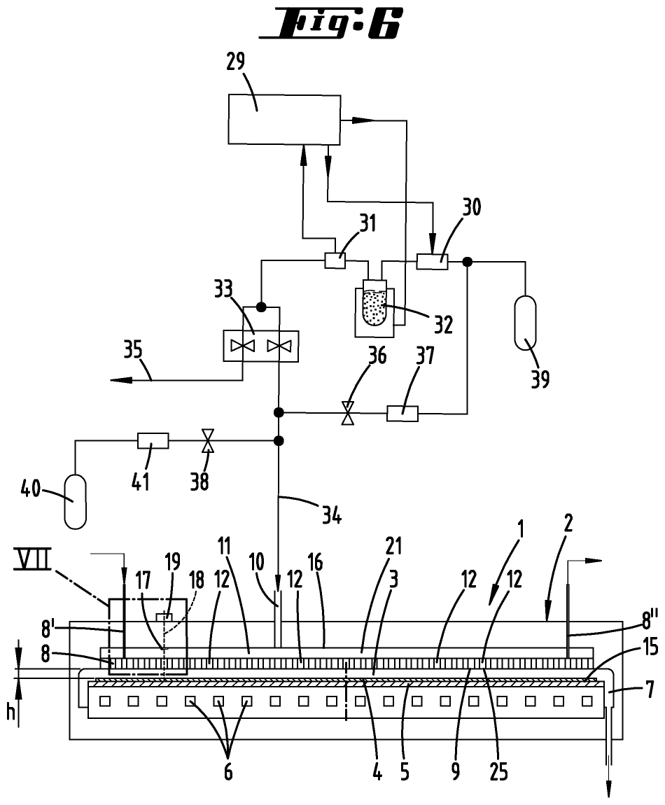

One of the tubes 12′ is used as a passage channel for a beam path 18 of an optical device. The cover plate 16 of the gas inlet element 2 has a window 17, through which the beam path 18 passes. The beam path 18 runs between a pyrometer 19, which is a two-wavelength pyrometer, and the support surface 15 or the surface of the substrate 4 that lies on the support surfaces 15. The pyrometer 19 can be used to measure the temperature of the substrate surface. FIGS. 4a and 5 show measuring curves that were measured over time t, and can be interpreted as measured temperature values. The temperature rises up to a maximum in the heating process. The measuring curve then drops off slightly along a straight line with a roughly constant gradient. FIG. 4a shows a first peak 27. FIG. 5 additionally shows a second peak 27′.

FIG. 4a shows a measuring curve, in which a flow of a reactive gas (for example, methane) or a mixture of several reactive gases with a mass flow rate of Q₁ is fed into the process chamber at a point in time t₁. The mass flow rate of the process gases is steadily increased up to a time t₂. Time t₂ is characterized in that the gradient of the measuring curve 26 rises. Observations have shown this to be correlated with the event where layer growth starts on the layer. As the peak 27 forms, the gradient of the measuring curve 26 then constantly changes during layer deposition, such that the gradient drops until it once again rises at a point in time t₄. Observations have shown that the rise in the measuring curve is accompanied by an end to the two-dimensional growth.

While the flow of the process gas was turned off at point in time t₄ in the measuring curve according to FIG. 4a, process gas was fed into the process chamber even after the peak 27 while recording the measuring curve according to FIG. 5. The peak 27′ formed in the process.

Based on the findings, the method according to the invention is implemented as follows:

The method according to the invention begins with the provision of a CVD reactor of the kind described above. A substrate 4 to be coated is placed in the CVD reactor. The substrate is located on the support surface 15. The temperature of the substrate 4 is increased by means of the heating device 6 from a point in time denoted with t₁ on FIG. 3. In the exemplary embodiment, a gas flow with a low mass flow rate Q₁ of the process gas (for example, methane during the deposition of graphene) can be fed into the process chamber. The mass flow rate Q₁ is lower than a mass flow rate sufficient to cause layer growth. However, it can also be provided that the substrate 4 only be heated in the presence of a carrier gas, for example argon, and the process gas only be switched on at a later point in time.

After the substrate surface has reached the process temperature T_{P}, which can lie above 1000° C., the mass flow rate of the process gas is continuously or incrementally linearly or nonlinearly increased. The surface of the substrate 4 is here observed by means of the pyrometer 9. The measuring curve initially runs along a straight line, until the gradient of the measuring curve changes by rising. At the point in time t₂ where the rise in the measuring curve is detected, the mass flow rate Q₂ of the process gas is stored. A third mass flow rate Q₃ is calculated by adding a prescribed value to the second mass flow rate Q₂. The mass flow rate is then increased up to the third mass flow rate Q₃. This third mass flow rate Q₃ is maintained for the layer growth. The prescribed value by which the mass flow rate is increased beyond the second mass flow rate Q₂ or the difference between the third mass flow rate Q₃ and second mass flow rate Q₂ can measure 20 percent of the second mass flow rate Q₂.

Layer deposition continues until such time as a second event is determined while observing the measuring curve 26, in which the measuring curve rises again after a preceding drop in the gradient of the measuring curve 26. This event takes place at time t₄, and is taken as a reason for switching off the supply of process gas.

A silicon carbide-coated susceptor can be used during the deposition of hBN. Among others, NH₃ is used as a reactive gas of the process gas in prior art. This gas acts on uncoated graphite. On the other hand, silicon carbide reacts with hydrogen at substrate temperatures in excess of 1300° C. Borazine (B₃N₃H₆) can be used as the reactive gas. This makes it possible to deposit hBN at temperatures ranging between 1400° C. and 1500° C. A noble gas, for example argon, is used as the carrier gas or inert gas.

The growth rate with a prescribed speed depending on the increase in mass flow rate from the second to third mass flow rate is increased as growth starts from a very low value to a higher value with the method according to the invention. This makes it possible to control the initial growth, in particular of graphene, and reduces the number of germination sites, thereby raising the quality of the two-dimensional graphene layer.

The method according to the invention relates to all material pairs mentioned at the outset, and in particular to the deposition of two-dimensional heterostructures.

The above statements serve to explain the inventions covered by the application as a whole, which each also independently advance the prior art at least by the following feature combinations, wherein two, several or all of these feature combinations can also be combined, specifically

A method, characterized in that a gas flow with a first mass flow rate Q₁ of the process gas is initially fed into the process chamber 3 while heating or after heating the substrate 4 to the process temperature T_{P}, wherein no layer growth takes place on the surface of the substrate 4, after which the mass flow rate is increased during observation of the substrate surface until layer growth starts at a second rate Q₂, and the mass flow rate is then increased to a third rate Q₃ corresponding to the sum of the second rate Q₂ with a prescribed value, and the layer is deposited at the third rate Q₃.

A use, characterized in that a gas flow with a first mass flow rate Q₁ of the process gas is initially fed into the process chamber 3 while heating or after heating the substrate 4 to the process temperature T_{P}, wherein no layer growth takes place on the surface of the substrate 4, after which the mass flow rate is increased during observation of the substrate surface until layer growth starts at a second rate Q₂, and the mass flow rate is then increased to a third rate Q₃ corresponding to the sum of the second rate Q₂ with a prescribed value, and the layer is deposited at the third rate Q₃.

A method or use, characterized in that an optical device 19 is used or provided on the CVD reactor 1 for observing the substrate surface.

A method or use, characterized in that the optical device 19 is a pyrometer and/or a two-wavelength pyrometer.

A method or use, characterized in that a measuring curve 26 of the optical device 19 recorded while observing the substrate surface is evaluated to determine when layer growth starts and/or that the start of layer growth is determined by detecting a change in the gradient of the measuring curve 26 of the optical device 19, wherein the change in particular is a rise or a drop.

A method, in which the measuring curve is used to determine the number of deposited layers and/or the number of deposited layers is determined by ascertaining the number of maximums or minimums in the measuring curve.

A method or use, characterized in that the prescribed value is greater than 0 and/or is at least 5 percent of the second mass flow rate Q₂, or at least 10 percent of the second mass flow rate Q₂, or at least 20 percent of the second mass flow rate Q₂.

A method or use, characterized in that the gas inlet element 2 has a gas outlet surface 25, which extends over a support surface 15 of the susceptor 5 and has a plurality of uniformly distributed gas outlet openings 14, 24 that are connected with a gas distribution volume 11, 21 in terms of flow.

A method or use, characterized in that the gas outlet surface 25 is comprised of a gas outlet plate 9 of the gas inlet element 2, which is adjoined by a cooling chamber 8 through which a coolant flows.

A method or use, characterized in that a beam path 18 of the optical device 19 passes through the gas inlet element 2 and/or that a cover plate 16 of the gas inlet element 2 has a window 17 transparent for the used wavelengths, and a tube 12′ through which the beam path 18 passes empties into the gas outlet surface 25.

A method or use, characterized in that a distance between a support surface 15 of the susceptor 5 and the gas outlet surface 25 is changed during deposition.

A method or use, characterized in that the process gas is generated by passing a carrier gas through a bubbler 32, 32′ containing a solid or liquid starting material.

A method or use, characterized in that a gas concentration measuring device 31, 31′ is used downstream from the bubbler 32, 32′ to determine the concentration of vapor of the starting material in the carrier gas.

A method or use, characterized in that the surface is further observed and/or the measuring curve 26 is further evaluated during layer deposition, so as to switch off the process gas if an event arises, and/or that the gas flow of the process gas is switched off when a change in the gradient of the measuring curve 26 is detected, wherein the change in particular is a rise or a drop.

All disclosed features (whether taken separately or in combination with each other) are essential to the invention. The disclosure of the application hereby also incorporates the disclosure content of the accompanying/attached priority documents (copy of the prior application) in its entirety, also for the purpose of including features of these documents in claims of the present application. Even without the features of a referenced claim, the subclaims characterize standalone inventive further developments of prior art with their features, in particular so as to submit partial applications based upon these claims. The invention indicated in each claim can additionally have one or several of the features indicated in the above description, in particular those provided with reference numbers and/or indicated on the reference list. The invention also relates to design forms in which individual features specified in the above description are not realized, in particular if they are recognizably superfluous with regard to the respective intended use, or can be replaced by other technically equivalent means.

Reference List

| | |
|---|---|
| 1 | CVD reactor |
| 2 | Gas inlet element |
| 3 | Process chamber |
| 4 | Substrate |
| 5 | Susceptor |
| 6 | Heating device |
| 7 | Gas outlet element |
| 8 | Cooling chamber |
| 8′ | Feed line |
| 8″ | Discharge line |
| 9 | Gas outlet plate |
| 10 | Feed line |
| 11 | Gas distribution chamber |
| 12 | Tube |
| 12′ | Tube |
| 13 | Intermediate plate |
| 14 | Gas outlet opening |
| 15 | Support surface |
| 16 | Cover plate |
| 17 | Window |
| 18 | Beam path |
| 19 | Optical device, pyrometer |
| 20 | Feed line |
| 21 | Gas distribution chamber |
| 22 | Tube |
| 23 | Intermediate plate |
| 24 | Gas outlet opening |
| 25 | Gas outlet surface |
| 26 | Measuring curve |
| 27 | Peak |
| 27′ | Peak |
| 28 | Mass flow rate |
| 29 | Control |
| 30 | Mass flow controller |
| 30′ | Mass flow controller |
| 31 | Concentration measuring device |
| 31′ | Concentration measuring device |
| 32 | Bubbler |
| 32′ | Bubbler |
| 33 | Switching valve |
| 33′ | Switching valve |
| 34 | Run line |
| 34′ | Run line |
| 35 | Vent line |
| 36 | Valve |
| 36′ | Valve |
| 37 | Mass flow controller |
| 37′ | Mass flow controller |
| 38 | Valve |
| 38′ | Valve |
| 39 | Inert gas source |
| 39′ | Inert gas source |
| 40 | Reactive gas source |
| 40′ | Reactive gas source |
| 41 | Mass flow controller |
| 41′ | Mass flow controller |
| Q₁ | Mass flow rate |
| Q₂ | Mass flow rate |
| Q₃ | Mass flow rate |
| T_{P} | Process temperature |
| h | Process chamber height, distance |
| t₁ | Point in time |
| t₂ | Point in time |
| t₃ | Point in time |
| t₄ | Point in time |

1. A method for depositing a two-dimensional layer onto a substrate in a chemical vapor deposition (CVD) reactor (1), the method comprising:
feeding process gas into a process chamber (3) via a gas inlet element (2) with gas outlet openings (14, 24);
bringing the process gas or its decomposition products into contact with a surface of the substrate (4) in the process chamber (3); and
heating the substrate (4) to a process temperature (T_{P}) so that the two-dimensional layer is deposited onto the surface of the substrate (4) after a chemical reaction of the process gas,
wherein feeding the process gas into the process chamber (3) comprises:
flowing the process gas with a first mass flow rate (Q₁) into the process chamber (3) while heating or after heating the substrate (4) to the process temperature (T_{P}), at which no layer growth takes place on the surface of the substrate (4),
after the substrate (4) has been heated to the process temperature (T_{P}), increasing the flow of the process gas to a second mass flow rate (Q₂) at which the layer growth on the surface of the substrate (4) starts to occur,
increasing the flow of the process gas to a third mass flow rate (Q₃) corresponding to a sum of the second mass flow rate (Q₂) with a prescribed value, and
maintaining the flow of the process gas at the third mass flow rate (Q) during which the two-dimensional layer is deposited.

2. A chemical vapor deposition (CVD) reactor (1) for depositing a two-dimensional layer onto a substrate (4), the CVD reactor (1) comprising:
a process chamber (3);
a gas inlet element (2) with gas outlet openings (14, 24) that empty into the process chamber (3);
a susceptor (5) for supporting the substrate (4);
a heating device (6) for heating the substrate (4) to a process temperature (T_{P});
a feed line (10) for flowing a process gas into the gas inlet element (2) through the gas outlet openings (14, 24) and into the process chamber (3); and
a control device (29) configured to control one or more components of the CVD reactor (1) so as to:
flow the process gas with a first mass flow rate (Q₁) into the process chamber (3) while heating or after heating the substrate (4) to the process temperature (T_{P}), at which no layer growth takes place on a surface of the substrate (4),
after the substrate (4) has been heated to the process temperature T_{P}) increase the flow of the process to a second mass flow rate (Q₂) at which the layer growth on the surface of the substrate (4) starts to occur,
increase the flow of the process gas to a third mass flow rate (Q₃) corresponding to a sum of the second mass flow rate (Q₂) with a prescribed value, and
maintain the flow of the process gas at the third mass flow rate (Q) during which the two-dimensional layer is deposited on the surface of the substrate (4).

3. The CVD reactor (1) of claim 2, further comprising an optical device (19) for observing the surface of the substrate (4).

4. The CVD reactor (1) of claim 3, wherein the optical device (19) is a pyrometer.

5. The method of claim 17, wherein at least one of:
a starting time of the layer growth is determined by evaluating a measuring curve (26) recorded by the optical device (19), or
the starting time of the layer growth is determined by detecting a change in a gradient of the measuring curve (26) recorded by the optical device (19).

6. (canceled)

7. The method of claim 5, wherein the measuring curve (26) is used to determine a number of deposited layers.

8. The method of claim 1, wherein the prescribed value is at least 5 percent of the second mass flow rate (Q₂).

9. The CVD apparatus (1) of claim 2, further comprising:
a cooling chamber (8) through which a coolant flows; and
a gas distribution volume (11, 21),
wherein the gas inlet element (2) has a gas outlet surface (25), which extends over a support surface (15) of the susceptor (5),
wherein the gas outlet openings (14, 24) are uniformly distributed over the gas outlet surface (25) and are fluidly connected with the gas distribution volume (11, 21),
wherein the gas outlet surface (25) comprises a gas outlet plate (9) of the gas inlet element (2), and
wherein the gas outlet plate (9) is adjoined by the cooling chamber (8).

10. (canceled)

11. The CVD apparatus (1) of claim 9,
wherein a beam path (18) of the optical device (19) passes through the gas inlet element (2), and
wherein a cover plate (16) of the gas inlet element (2) has (i) a window (17) that is transparent to a wavelength of radiation emitted by the optical device (19), and (ii) a tube (12′) through which the beam path (18) opens into the gas outlet surface (25).

12. The method of claim 1, wherein a distance between a support surface (15) of the susceptor (5) and a gas outlet surface (25) of the gas inlet element (2) is changed during the deposition of the two-dimensional layer.

13. The method of claim 1, wherein the process gas is generated by passing a carrier gas through a bubbler (32, 32′) containing a solid or liquid starting material.

14. The method of claim 13, wherein a gas concentration measuring device (31, 31′) downstream from the bubbler (32, 32′) is used to determine a concentration of a vapor of the starting material in the carrier gas.

15. The method of claim 17, wherein the surface of the substrate (4) is further observed and the measuring curve (26) is further evaluated during layer deposition so as to switch off the process gas when a change in a gradient of a measuring curve (26) recorded by the optical device (19) is detected.

16. (canceled)

17. The method of claim 1, wherein an optical device (19) is used to observe the surface of the substrate (4).

18. The method of claim 17, wherein the optical device (19) is a pyrometer.

19. The method of claim 18, wherein the pyrometer is a two-wavelength pyrometer.

20. The method of claim 7, wherein the number of deposited layers is determined by ascertaining a number of maximums or minimums present in the measuring curve (26).

21. The CVD reactor (1) of claim 4, wherein the pyrometer is a two-wavelength pyrometer.

22. The CVD reactor (1) of claim 2, further comprising a bubbler containing a solid or liquid starting material, wherein the process gas is generated by passing a carrier gas through the bubbler (32, 32′).

23. The CVD reactor (1) of claim 22, further comprising a gas concentration measuring device (31, 31′) disposed downstream from the bubbler (32, 32′), wherein the gas concentration measuring device (31, 31′) is configured to determine a concentration of a vapor of the starting material in the carrier gas.
